(19) United States
(12) Patent Application Publication
(10) Pub. No.: US 2026/0136511 A1
(43) Pub. Date: May 14, 2026

(54) HIGH-HEAT-DISSIPATION HYBRID-COMPOSITE HEAT SINK HAVING SMOOTH ELECTROMAGNETIC WAVE SHIELDING

(71) Applicants: Janie LEE, Seongnam-si (KR); Minho NAM, Ansan-si (KR); Sangyoung JUN, Ansan-si (KR)

(72) Inventors: Janie LEE, Seongnam-si (KR); Minho NAM, Ansan-si (KR); Sangyoung JUN, Ansan-si (KR)

(21) Appl. No.: 18/952,563

(22) Filed: Nov. 19, 2024

(30) Foreign Application Priority Data
Nov. 8, 2024 (KR) 10-2024-0158001

(51) Int. Cl. H05K 9/00; H05K 7/20

(52) U.S. Cl. CPC H05K 9/0024; H05K 7/2039

(57) ABSTRACT

Disclosed is a high-heat-dissipation hybrid-composite heat sink having smooth electromagnetic wave shielding, which is configured by interfacially bonding a shield can to a heat sink made of a plate material with high thermal conductivity without an air gap. While electricity is conducted and grounded to ensure smooth electromagnetic shielding, heat dissipation performance is improved through a small number of layers and zero air gap, and miniaturization and weight reduction thereof can be achieved.

### BACKGROUND OF THE PRESENT INVENTION

### Field of the Present Invention

The present invention relates to a heat sink for dissipating heat from various types of electronic devices.

### Description of the Related Art

Recently, the era of ubiquitous and digital convergence related to displays and Al autonomous driving, which are rapidly developing, is entering. Accordingly, various components thereof are rapidly becoming smaller and slimmer.

In this way, as various components are integrated, more heat is generated, and this heat emission not only reduces the functions of the components, but also causes malfunction of surrounding components and deterioration of the substrate.

In particular, high-power consumption products such as power devices and LED modules generate a lot of heat, and it is difficult to control the heat emission.

Accordingly, there is an increasing demand for lightweight heat sinks, but there is an urgent need for research to overcome the heat dissipation limitations, large volume, and heavy weight of aluminum die-casting materials, which are most commonly used in automobiles, electric vehicles, and LEDs.

More specifically, the aluminum die-casting materials are composed of two types of alloys such as ADC10 and ADC12, which have good structural and mechanical properties, accounting for about 98% of die-casting production. These materials are mainly composed of alloys of aluminum, copper, and silicon, and contain about 10 wt % of silicon.

Since this silicon is not a metal material, it reduces thermal conductivity.

In the case of aluminum 1050, aluminum sheet (plate) produced by an actual rolling process has a thermal conductivity of 237 W/mk, while the aluminum die-casting materials have a thermal conductivity of only 96 to 100 W/mk.

As a technology related to resolving these problems, “Heat sink structure and manufacturing method thereof” (Korean Patent Publication No. 10-2024-0016878, Patent Literature 1) discloses a case in which a heat sink body part and a heat dissipation fin part are joined by laser welding, so that the heat sink body part can be made of a single cast aluminum part with high thermal conductivity.

In the above-mentioned Patent Literature 1, the heat dissipation fins can be made very thin by welding them to the heat sink body, thereby ensuring sufficient heat dissipation surface area and improving heat dissipation efficiency.

In the meantime, the key in heat dissipation technology is to minimize the air cap between the heat source and the heat sink. However, as mentioned above, in a case of the conventional die-casting heat sink, there is also a problem in that the heat dissipation effect is reduced because the air cap could not be minimized due to the die-casting molding being performed to maximize the heat dissipation effect by maximizing the air contact area and the heat sink manufacturer and the lower component manufacturer being different from each other.

Rather, in “Electronic device enclosures and heat sink structure with thermal management features” (Korean Patent Registration No. 10-1472721, Patent Literature 2), an air gap is formed inside the housing surrounding the heat sink structure. The air gap in this patent Literature 2 provides a uniform heat transfer effect, but as anyone skilled in the art would know, in order to increase the heat dissipation effect, the air gap must be minimized, and this is even more necessary for heat dissipation components with a multilayer structure.

FIG. 1 illustrates a structure of layers for heat dissipation of AP chips in current smartphones. From top to bottom, it takes the layers of vapor chamber, PCM/Gap Pad, shielding sheet, paste, shield can, and AP chip, and the shielding sheet takes the structure of ceramic heat dissipation coating, plating fabric, and conductive adhesive. However, since there are too many layers, the occurrence of air caps increases, making effective heat dissipation difficult, and causing many problems due to heat generation issues.

Here, an opening is formed in the shield can, so that the heat generated from the chip is transferred to the thermal conductive sheet through the opening.

Of course, there are also examples of placing a thermally conductive sheet in this opening, but since an air gap is generated on the adhesive surface of this thermally conductive sheet, it is insufficient to solve the problem of heat generation.

Meanwhile, an emissivity refers to the efficiency of surface energy emission of an object when radiating heat, and thermal radiation (emission) is electromagnetic radiation, including both visible light and invisible infrared rays, and is a numerical value of the heat energy absorbed or emitted by the surface of water.

In general, the higher the emissivity value, the more heat energy is emitted to the outside.

The emissivity value of the pure aluminum plate is measured as 0.513 W/mk as shown in FIG. 2, and when the same material is subjected to a heat-dissipative coating, the emissivity is measured as 0.901 W/mk as shown in FIG. 3. Therefore, it can be seen that the emissivity is improved after the heat-dissipative coating, releasing more heat energy than before the coating, thereby significantly improving the heat dissipation effect.

Generally, the heat dissipation effect is improved by 10 to 15 degrees based on 100 degrees Celsius, compared to a pure aluminum material before coating.

Since the pure aluminum plates release only about 50% of the heat and retain it as internal heat, the heat dissipation effect of the chip is low. However, after heat dissipation coating, since about 90% of the heat is released and about 10% is retained as internal heat, when heat dissipation coating is applied to the surface of the aluminum heat sink, the heat dissipation effect can be improved.

However, when applying the existing heat-dissipating coating to the aluminum die-casting materials, it is necessary to apply heat-dissipating paint after chromating for durability in order to prevent corrosion and strengthen adhesion as a pretreatment.

In this case, the cost of painting is high, so the heat dissipation coating is usually not applied to the die-cast material.

In the end, since the performance of the chip continues to improve through upgrades, the heat generated by the chip increases, so that the size of the heat sink has no choice but to increase in order to solve this problem.

In addition, as an example of why the heat sink is made of aluminum die-casting material, when multiple heat sources with different heights are placed at the bottom of the heat sink, multiple protrusions with different heights are usually placed at the bottom to release the heat from the heat sources. At this time, the die-casting material is also used to form these multiple protrusions.

However, as mentioned above, the die-casting material has limitations, which causes the problem of reduced heat dissipation performance.

### PATENT LITERATURE

Patent Literature 1: Korean Patent Publication No. 10-2024-0016878 (Feb. 6, 2024)
Patent Literature 2: Korean Patent Registration No. 10-1472721 (Dec. 8, 2014)

### SUMMARY OF THE PRESENT INVENTION

The present invention aims to solve the problems arising in the prior art described above and is to provide a high-heat-dissipation hybrid-composite heat sink having smooth electromagnetic wave shielding, which minimizes the number of layers and suppresses air gaps through surface-to-surface bonding of contact surfaces between the layers, thereby improving heat dissipation performance thereof, and also enables electromagnetic wave shielding, which is the basic purpose of a shield can, to be smoothly achieved.

Further, the present invention is to provide an ultra-compact and ultra-light heat dissipation structure that improves heat dissipation performance and has light weight and small volume by solving problems of a die casting material in the prior art which has heat dissipation performance degraded due to inclusion of a foreign substance and has large volume and heavy weight.

More specifically, a heat sink and a shield can, such as a vapor chamber, are surface-to-surface bonded (a metal component of the vapor chamber is interfacially bonded to the shield can) through side surfaces around an opening to be electrically connected, so that they can be grounded to ensure smooth electromagnetic wave shielding. In addition, since the heat sink and the shield can are surface-bonded to each other, the number of the layers is minimized with a three-layer structure of an AP chip, a TIM, and a heat sink, thereby achieving an air gap minimization and improving a heat dissipation effect.

In addition, unlike die casting which is a metal casting process of forcing molten metal to be injected into a mold under high pressure, the present invention is to provide a heat sink having high heat dissipation performance for the same weight and volume, the heat sink being made of a plate, an extruded material, a vapor chamber, a heat pipe, or the like which has a maximized content of metal with a high thermal conductivity to minimize weight and volume compared to the die casting material and minimizing the number of layers by performing surface-to-surface bonding to an attachment under the heat sink such as interfacial bonding while air gaps are minimized compared to the prior art.

According to an aspect of the present invention to achieve the object described above, there is provided a high-heat-dissipation hybrid-composite heat sink having smooth electromagnetic wave shielding including: a heat sink (1) that is made of any one of materials such as aluminum, copper, magnesium, stainless steel, gold, silver, titanium, iron, nickel brass, carbon fiber, and clad metal and is formed in any one form of a plate, an extruded material, a vapor chamber, or a heat pipe; and an attachment (13) that is positioned under the heat sink (1) and has an opening (7a) formed in a center of a contact surface with the heat sink (1) and an upper surface around the opening (7a) surface-bonded to the heat sink (1) without an air gap.

In the above configuration, the attachment (13) is surface-bonded to the heat sink without an air gap by any one method of arc stud welding, ultrasonic welding, spark plasma sintering welding, laser welding, brazing, soldering, or insulation bonding.

In the above configuration, the attachment (13) includes a chip (5); a TIM (6) formed on an upper portion of the chip (5); and a shield can (7) having a plate-shaped upper surface positioned on an upper portion of the TIM (6), the opening (7a) formed in a center thereof, and a side portion that forms a wall surface bent downward.

In the above configuration, a lower end of the wall surface of the shield can (7) is grounded and the shield can (7) and the heat sink (1) are interfacially bonded with a conductive material to shield electromagnetic waves.

In the above configuration, the TIM (6) is also placed between the heat sink (1) and the shield can (7), but a protrusion (14) is formed in which an outer perimeter of the heat sink (1) protrudes downward or an outer perimeter of the shield can (7) protrudes upward, so that the heat sink (1) and the shield can (7) are surface-bonded to each other through the cross section of the protrusion (14).

In the above configuration, on the heat sink (1), a heat dissipation coating layer (11) is formed by roll coating.

### BRIEF DESCRIPTION OF THE DRAWINGS

The above and other objects, features and advantages of the present invention will be more apparent from the following detailed description taken in conjunction with the accompanying drawings, in which:

FIG. 1 is a drawing showing a layer structure for the heat dissipation of an AP chip a smartphone;

FIG. 2 is a test report showing an emissivity of an aluminum plate;

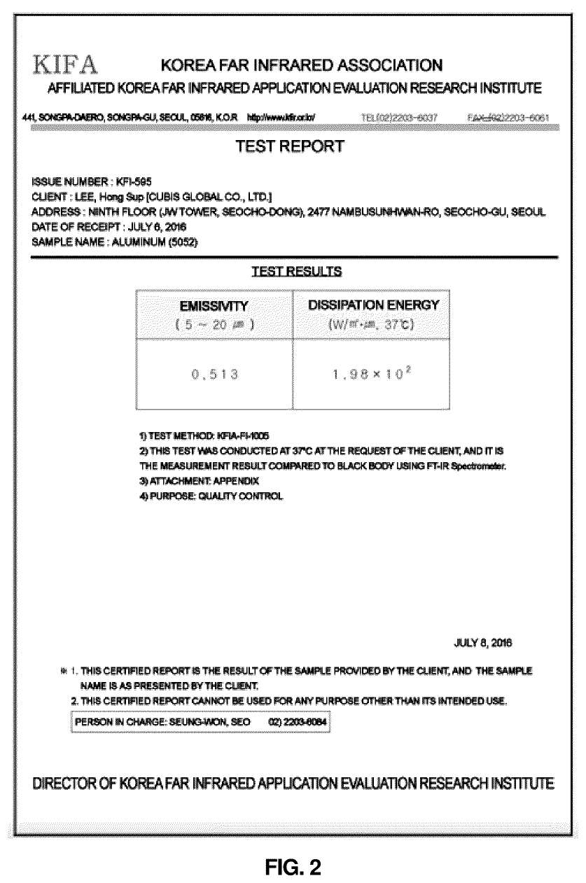

FIG. 3 is a test report showing an emissivity after heat dissipation coating treatment on an aluminum plate;

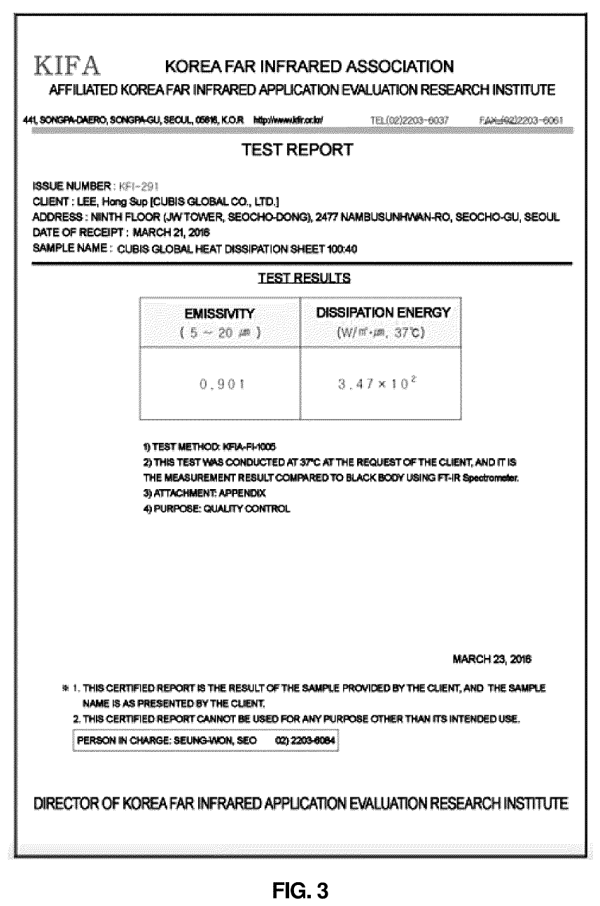

FIGS. 4A to 4F are drawings showing an embodiment of the present invention;

FIG. 5 is a drawing showing a comparison of the interface structure of a conventional heat dissipation method and a heat dissipation method of the present invention;

FIG. 6 is a photograph showing a specimen for a heat dissipation test in the present invention;

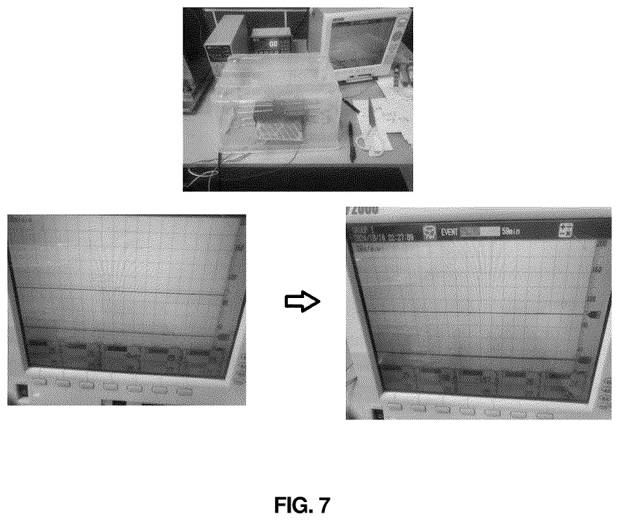

FIG. 7 is a photograph showing equipment settings and experimental results for the heat dissipation test of a die-casting material;

FIG. 8 and FIG. 9 are photographs showing equipment settings and experimental results for the heat dissipation test of a heat dissipation coated aluminum plate;

FIG. 10 is a photograph showing a protrusion on the bottom of a heat sink of a general die casting material;

FIGS. 11A to 11D are drawings showing an example of the arc stud welding for forming a protrusion corresponding to the protrusion of FIG. 10; and

FIG. 12 is a process diagram showing an example of a process for manufacturing a heat sink of the present invention.

### REFERENCE SIGNS LIST

1: heat sink
5: chip
6: TIM
7: shield can
7a: opening
11: heat dissipation coating layer
13: attachment
14: protrusion

### DETAILED DESCRIPTION OF THE PREFERRED EMBODIMENT

Hereinafter, a high-heat-dissipation hybrid-composite heat sink having a smooth electromagnetic wave shielding of the present invention will be described in detail with reference to the accompanying drawings.

The ultra-compact high-heat-dissipation hybrid-composite heat sink of the present invention includes a heat sink (1) and an attachment (13) under the heat sink.

The heat sink (1) that is a configurational element of the present invention is made of any one of materials such as aluminum, copper, magnesium, stainless steel, gold, silver, titanium, iron, nickel brass, carbon fiber, and clad metal and is formed in any one form of a plate, an extruded material, a vapor chamber, or a heat pipe.

As described above, in the case of an aluminum die casting material, the thermal conductivity is decreased similarly to that of silicon for formability. Hence, in the present invention, a material that has a foreign substance for die casting added is not used.

By using an aluminum plate material (thermal conductivity: 237 Watts) instead of the aluminum die casting (thermal conductivity: 96 to 100 Watts) material, a material having approximately 2.4 times better thermal conductivity than that of the die casting material is used to achieve better heat dissipation.

When aluminum is described as an example, comparison of the advantages and disadvantages between an aluminum plate and an aluminum die casting material is as illustrated in Table 1 below.

TABLE 1

| Item | Plate | Die casting |
|---|---|---|
| Material price | Middle price | Low price |
| Weldability | Very good | Non-weldable |
| Thermoelectric | 237 Watts | 96-100 Watts |
| conductivity | | |
| Shape processing | Partially restricted | Very good |
| Heat dissipation | Good | Bad |
| performance | | |
| Coatability | Good | Fair |

A major disadvantage of the die casting material is critical in that about 10 wt % of a silicon (Si) component is contained and prevents welding.

Consequently, it is practically impossible to produce an integral structure of the heat sink, and thus it is basically impossible to improve thermal conduction through welding.

Consequently, it is practically impossible for an aluminum die casting material to reduce the weight and the volume of the heat sinks, while an aluminum plate can overcome limitations of shape processing through welding, thereby improving heat dissipation performance while weight, volume, and costs are reduced, and thus the aluminum plate enables simultaneous innovative improvements to be achieved in various aspects.

In this case, a heat dissipation fin can be formed on the heat sink by welding.

An attachment (13) that is a configurational element of the present invention is positioned under the heat sink (1) and has an opening (7a) formed in a center of a contact surface with the heat sink (1) and an upper surface around the opening (7a) surface-bonded to the heat sink without an air gap.

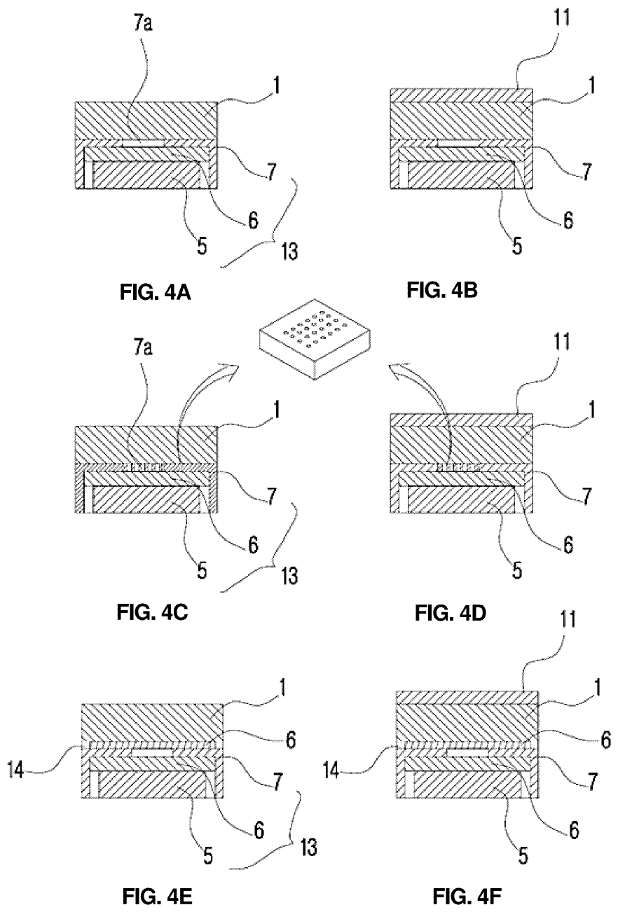

More specifically, as illustrated in FIG. 4A, the attachment (13) may include a chip (5), a TIM (6) formed on an upper portion of the chip (5), and a shield can (7) having a plate-shaped upper surface positioned on an upper portion of the TIM (6), the opening (7a) formed in a center thereof, and a side portion that forms a wall surface bent downward.

Here, the upper surface around the opening (7a) of the shield can (7) is surface-bonded to the heat sink (1) without an air gap.

In addition, the size of the opening (7a) can be increased or decreased depending on the heat dissipation conditions and electromagnetic wave shielding conditions.

Here, an example of a method of performing integral surface-to-surface bonding of the heat sink to the shield can (7) is any one method of arc stud welding, ultrasonic welding, spark plasma sintering welding, laser welding, brazing, soldering, or insulation bonding.

Insulation bonding refers to using single insulating material such as ALN, BN, SIC, MGO, or alumina or using a combination thereof, during bonding of copper foil and an aluminum sheet used when a metal PCB is manufactured. The insulation bonding can be mostly used at 1 to 10 Watts and enables two effects of facilitating mass bonding and improving vertical thermal conductivity to be simultaneously realized.

The aforementioned bonding methods are methods for enabling surface-to-surface bonding by minimizing air gaps. The arc stud welding is a welding method using basic principles of arc welding and resistance welding and is referred to as STUD, STUD Bolt, STUD Anchor, STUD PIN, or the like.

More specifically, the arc stud welding is generally referred to as stud welding that is a type of melt bonding for joining to a workpiece (base material), an innovative welding method of instantaneously depositing on two surfaces that are to be attached to each other, which is a technical method of bonding members in a certain form in a very economical time and cost and enabling a spatial advantage and mass welding to be achieved.

In addition, corrosion does not occur when a member having a diameter of 3 mm to 10 mm is welded while pressure is applied and joining is performed within a short time (0.1 sec. to 1.0 sec.) in a state in which the base material and the member are sufficiently heated by the electric arc and are melted.

Here, the arc stud welding can be performed on a member having a width of 40 mm depending on the arc capacity. In a case where the width is larger than 40 mm, the arc stud welding can be performed by executing a press process when a corner R value is increased. Depending on a shape, it is possible to use an insulator that is used for bonding copper foil of a metal PCB and an aluminum sheet.

The ultrasonic welding is a method of performing conversion to ultrasonic vibrational energy, transmitting the energy to a bonding target material, and bonding the material by pressure and heat generated due to friction. The ultrasonic welding is advantageous in that lower pressure is applied compared to cold pressure welding such that deformation is small, welding is performed in the same state as rolled, and dissimilar metal welding can be performed.

Moreover, very thin plates, that is, films, can also be easily welded; however, the welding strength varies significantly depending on thicknesses of the plates, and the thicker the plates, the lower the welding strength.

A welding device includes an ultrasonic generator, a vibrator, a vibration transmission mechanism, and a pressure welding tip. Bonding conditions vary depending on a type of bonding material and a thickness of a plate, but external deformation of a bonding portion is small, and it is easy for mass production.

This bonding method forms a surface-to-surface interfacial bonding surface, thus enabling no external damage and no deformation to occur and heat loss to be minimized.

In addition, among the brazing methods, high-frequency induction heating metal bonding is also one of the good methods.

This bonding method directly heats the heated object, so that it has better heat efficiency than heating methods such as heat reflection and heat conduction, allows for precise joining, does not damage the heated metal due to a non-contact heating, and has the advantage of local selection and rapid surface heating.

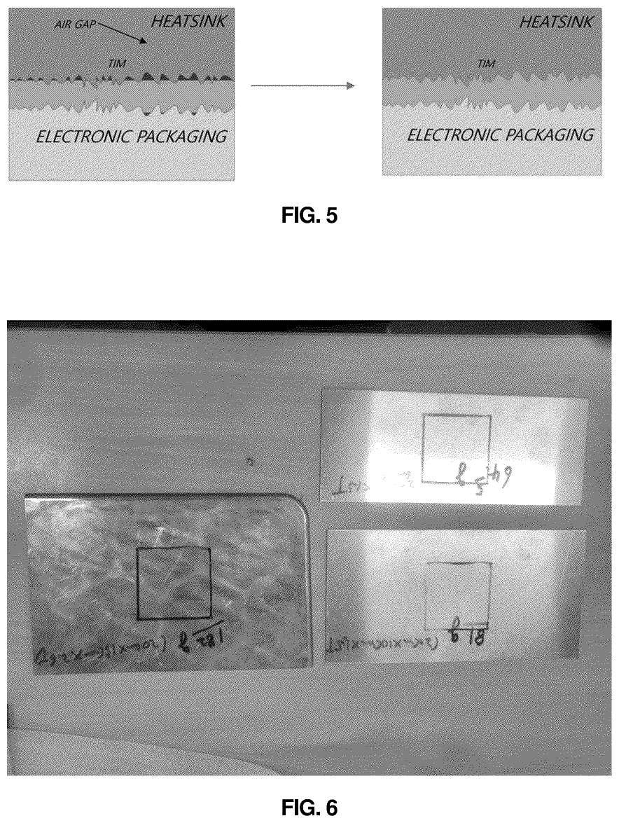

FIG. 5 specifically depicts a difference between the existing structure and a structure according to the present invention. In the prior art, an air gap that is not actually visible is formed in an interface between a shield can and a heat sink, and a phenomenon occurs in which this part blocks heat, increases thermal resistance, and hinders heat dissipation. Hence, to reduce this phenomenon, a gel or a phase change material (PCM) sheet is used, but these products are also significantly less effective in reducing the interface. However, it can be found that the structure of the present invention on the right side completely eliminates the air gap to reduce an insulation effect and enables smooth heat dissipation to be performed.

That is, the key to heat dissipation through this bonding structure is to minimize the boundary between layers and eliminate the air gap between the heat source and the heat sink as much as possible. By using multiple additional bonds, the temperature of one heat source is transmitted to the heat sink as much as possible by melting bonding both surfaces of the heat source and the heat sink or the material in the middle thereof and the heat sink without an air gap, thereby implementing a perfect heat dissipation effect. Therefore, it is possible to reduce the layers and dramatically improve the weight, the volume, and the economy of heat sinks, Metal PCBs, AP chips, CPUs, LEDs, OLED TVs, Telecom, VAG Display cards, Al Servers, and Gamming console for autonomous driving vehicle, which were previously unsolved problems.

In the above configuration, as shown in FIG. 4B, a heat dissipation coating layer (11) can be formed on the heat sink (1) by roll coating.

The heat dissipation coating layer (11) receives heat from the heat sink and dissipates and radiates the heat to the outside and can be made of various known heat dissipation coating materials.

Examples thereof include carbon nanotubes (CNT), nano ceramic, graphene, graphite, urethane, epoxy, silicone, acryl, PVDF, Teflon, and the like.

In this case, roll coating is suitable instead of spray coating, and can reduce consumption of a heat dissipation coating material to cut down manufacturing costs.

In a case where the heat dissipation coating layer (11) is formed on the heat sink (1), the emissivity increases based on a pure aluminum plate as described in background art, and thereby the heat dissipation effect increases.

Furthermore, in a case where the heat dissipation coating layer is applied to an upper side of a heat sink, such as the aluminum plate sheet described above, it is possible to reduce the weight and the volume by about ⅔ compared to a case of using only the die casting heat sink material, and thus not only the heat dissipation effect but also the lightweight and compact design can be achieved.

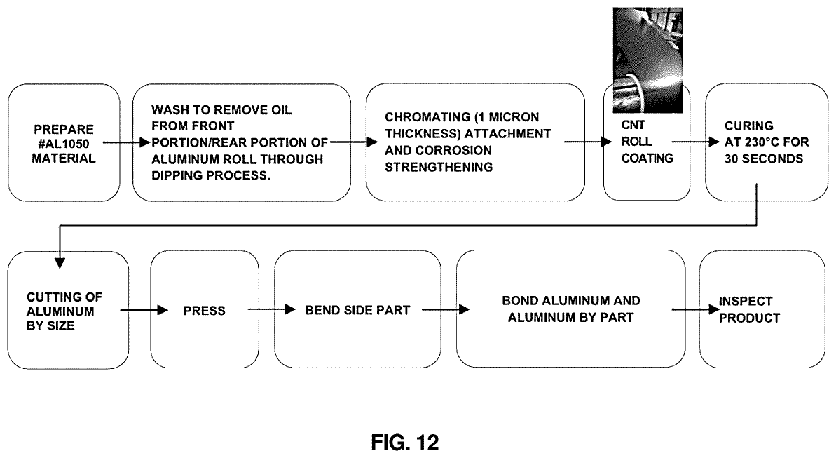

FIG. 12 depicts an example of a process of manufacturing the heat sink of the present invention in which the heat dissipation coating layer is formed.

In the drawing, it can be found that, after an aluminum plate is prepared and a front surface portion and a rear surface portion thereof is cleaned through a dipping process, the plate is coated with chromate for corrosion prevention, is coated with a CNT heat dissipation coating material by a roll coating method, cured, cut to match a product shape, and press-formed, a side is bent if necessary, the protrusion is formed for each portion in a case where undersurface protrusions need to be provided, and then the attachment is bonded to the plate to manufacture a product.

When applying the heat dissipation coating, it is recommended to use the roll coating, so that heat dissipation coating costs can be reduced by 80% compared to the spray coating.

### <Experimental Example 1> Heat Dissipation Test

A heat dissipation test was conducted.

First, an aluminum die casting material having a size of 20 cm×13 cm×2.6 T and weight of 182 g, a CNT coated aluminum #1050 plate having a size of 20 cm×10 cm×1.5 T and weight of 81 g, and a CNT coated aluminum #1050 plate having a size of 20 cm×8 cm×1.5 T and weight of 64.5 g are prepared (see FIG. 9).

Additionally, after a power supply, a temperature recorder, and a copper block equipped with an internal heater are prepared, heating is performed with input power of 30 Watts for one hour, and then temperatures at an initial state and after heating for one hour were measured.

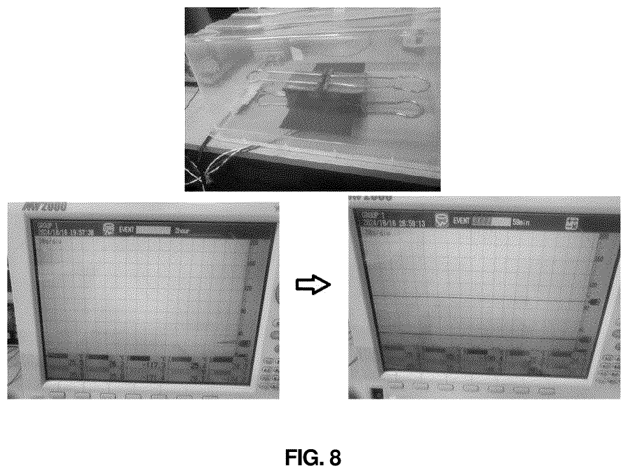

Heat source temperatures and indoor temperatures per unit time of the die casting material are listed in Table 2 below and FIG. 7.

TABLE 2

| | Heat source temperature | Indoor temperature |
|---|---|---|
| Test time | (° C.) | (° C.) |
| 0 min | 26.3 | 25.9 |
| 20 min | 81.7 | 26.0 |
| 30 min | 91.1 | 26.1 |
| 40 min | 96.3 | 26.1 |
| 50 min | 99.2 | 26.0 |
| 60 min | 100.8 | 26.1 |

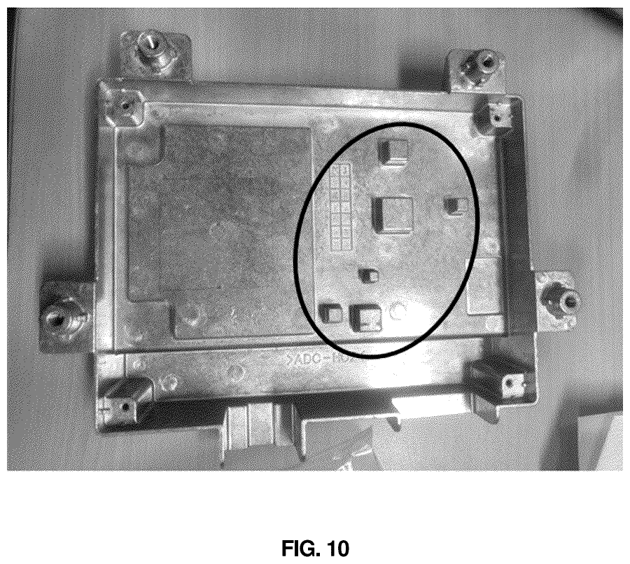

On a monitor screen in FIG. 10, number 2 indicates the heat source temperature, number 4 indicates the indoor temperature, and the test times of 0 min. and 60 min. are illustrated in FIG. 7.

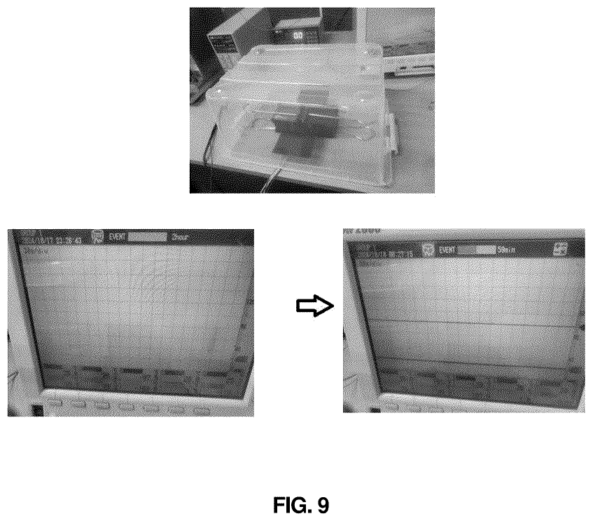

The heat source temperatures and the indoor temperatures per unit time of the CNT coated aluminum #1050 plate having the size of 20 cm×10 cm×1.5 T and the weight of 81 g are illustrated in Table 3 below and FIG. 8.

TABLE 3

| | Heat source temperature | Indoor temperature |
|---|---|---|
| Test time | (° C.) | (° C.) |
| 0 min | 26.2 | 25.4 |
| 20 min | 83.3 | 25.6 |
| 30 min | 89.9 | 25.8 |
| 40 min | 93.0 | 25.8 |
| 50 min | 94.6 | 25.9 |
| 60 min | 95.5 | 25.9 |

On a monitor screen in FIG. 8, number 2 indicates the heat source temperature, number 4 indicates the indoor temperature, and the test times of 0 min. and 60 min. are illustrated in FIG. 8.

The heat source temperatures and the indoor temperatures per unit time of the CNT coated aluminum #1050 plate having the size of 20 cm×8 cm×1.5 T and the weight of 64.5 g are illustrated in Table 4 below and FIG. 9.

TABLE 4

| | Heat source temperature | Indoor temperature |
|---|---|---|
| Test time | (° C.) | (° C.) |
| 0 min | 26.2 | 26.0 |
| 20 min | 88.1 | 26.2 |
| 30 min | 95.5 | 26.2 |
| 40 min | 99.1 | 26.2 |
| 50 min | 100.8 | 26.2 |
| 60 min | 101.7 | 26.2 |

The results of the experiment are summarized and listed in Table 5.

TABLE 5

| | Diecasting | | CNT coating | | CNT coating | |
|---|---|---|---|---|---|---|
| | (20 cm × 13 | | (20 cm × 10 | | (20 cm × 8 | |
| Item | cm × 2.6 T) | | cm × 1.5 T) | | cm × 1.5 T) | |
| Weight | 182 | g | 81 | g | 64.5 | g |
| Volume | 0.026 cm × 20 cm × | | 0.015 cm × 20 cm × | | 0.015 cm × 20 cm × | |
| | 13 cm = 6.76 cm³ | | 10 cm = 3 cm³ | | 8 cm = 2.4 cm³ | |
| Test Voltage | 30 | watts | 30 | watts | 30 | watts |
| Heat dissipation | 1 | hour | 1 | hour | 1 | hour |
| test time | | | | | | |
| Temperature | 100.8 | (° C.) | 95.5 | (° C.) | 101.7 | (° C.) |

Assuming that similar temperature results are obtained after one hour as a result of the experiment, the aluminum die casting material weighs 182 g while the CNT coated aluminum plates weigh 81 g and 64.5 g. Hence, it can be found that the weight required for a similar heat dissipation effect is much lighter.

Similarly, in the case of the volume, it can be found that the aluminum die casting material has a volume of 6.76 cm3 while the CNT coated aluminum plates have smaller volumes of 3 cm3 and 2.4 cm3.

That is, weight reduction of 63%, volume reduction of 65%, cost reduction of 30% can be achieved, and the heat dissipation performance can be improved by 50% or higher.

In the above-described configuration, it is preferable that an undersurface protrusion be formed on an undersurface of the heat sink to overcome a step of the attachment.

FIG. 10 illustrates a heat sink made of a general die casting material, with protrusions having different protrusion lengths which are formed to be in contact with chips having various heights.

This means that multiple resistors and chips are arranged under the heatsink and are formed with different heights to be in contact with the heat sink in a case where the resistors and the chips have different heights, respectively.

The protrusions can also be required by the present invention, and the heat sink made of a plate can be formed by press-forming the plate into a required shape.

Incidentally, in a case where multiple heat sources having different heights are arranged below the heat sink in general, multiple protrusions having different heights are formed to be in contact with these heat sources.

Incidentally, as described above, in a case where a heat sink is manufactured using a method of press-forming, there are difficulties in forming these protrusions having different heights.

In order to solve the difficulties, the undersurface protrusions formed on the undersurface of the heat sink can be formed by a method such as arc stud welding or ultrasonic welding, similar to the bonding of the heat sink and the attachment.

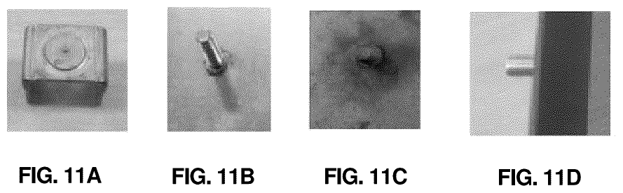

FIGS. 11A to 11D depict an example of the arc stud welding for this purpose.

First, in FIGS. 11B, 11C, and 11D, protrusions can be formed at low costs by bonding aluminum to aluminum or aluminum to copper through stud welding and then manufacturing male screws in round or quadrangular shapes depending on heights of PCB board components.

Further, the protrusions of FIG. 11A enable both surfaces to be completely melted and bonded and maximum heat dissipation effects to be maintained, and in the case of FIG. 11D, melting and bonding can be completely achieved without any damage to a coated surface.

A specific example of the present invention configured as described above is depicted in FIGS. 4A to 4F.

FIG. 4A illustrates an example in which the heat sink (1), the shield can (7), the TIM (6) or the paste, and the chip (5) are sequentially formed from top to bottom.

Here, instead of the AP chip (5), a CPU chip, an APU chip, an NPU chip, a TPU chip, an ASIC chip, or the like may be applied.

As is well known, the shield can (7) can be made of nickel brass such as C7521, C7541, or C7701, and the heat sink (1) includes a vapor chamber.

Further, the heat sink (1) is made of any one of materials such as aluminum, copper, magnesium, stainless steel, gold, silver, titanium, iron, nickel brass, carbon fiber, and clad metal and is formed in any one form of a plate, an extruded material, a vapor chamber, or a heat pipe.

The TIM (6) is made up of a PCM sheet, a heat dissipation tape, a heat dissipation gel, a thermal pad, an epoxy adhesive, or the like, based on a raw material such as silicone, carbon fiber, acryl, and urethane.

The shield can (7) has the opening (7a) formed in the center thereof and the upper surface around the opening (7a) is bonded to the heat sink (1) without an air gap by the above-described bonding method.

In the embodiment of the drawing, the surface bonding area may be the outer edge area of the shield can (7) or may be the entire surface excluding the opening (7a), but bonding the entire surface excluding the opening (7a) is more effective in increasing the heat dissipation effect without an air gap.

FIG. 4B has the same configuration as FIG. 4A thereof, and the above-described heat dissipation coating layer (11) is formed on the heat sink (1).

In a case where the heat sink (1) is made of a simple plate, the heat dissipation coating layer (11) can be formed by a roll coating method. When it is difficult to perform the roll coating, a spray coating method can be employed when heat dissipation fins are formed.

The heat dissipation coating layer (11) can be made of the above-described carbon nanotubes (CNT), nano ceramic, graphene, graphite, urethane, epoxy, silicone, acryl, PVDF, Teflon, or the like.

In FIG. 4C, unlike FIG. 4A, where one large opening (7a) is located in the center of the surface of the shield can (7), a plurality of small openings is positioned in the center of the surface of the shield can (7).

Here, the surface bonding between the shield can (7) and the heat sink (1) can be performed in the entire or part of the area excluding the small opening (7a), and it is most preferable to bond in the entire area.

Here, the shape of the opening (7a) is not limited to a circle, and various shapes such as a square, a triangle, and a star are possible.

FIG. 4D illustrates a configuration similar to that in FIG. 4C, but with the heat dissipation coating layer (11) is coated on the heat sink (1).

FIG. 4E is a configuration applied when the TIM (6) is to be applied to two locations, that is, the upper and lower portion of the shield can (7). As described above, in addition to the heat dissipation, the heat sink (1) and the shield can (7) are electrically and conductively bonded to each other for electromagnetic wave shielding.

That is, TIM (6) is also placed between the heat sink (1) and the shield can (7), but a protrusion (14) is formed in which the outer perimeter of the heat sink (1) protrudes downward or the outer perimeter of the shield can (7) protrudes upward, so that the heat sink (1) and the shield can (7) are surface-bonded to each other through the cross section of the protrusion (14).

In providing the heat sink (1) to which the attachment (13) is attached by complete surface-to-surface bonding as described above, the mounting tolerance needs to be provided in an actual current assembly site since components are delivered and assembled individually.

That is, in a case where the shield can (7) is bonded to the heat sink (1) by a method such as welding, it is difficult to perform assembly depending on site conditions in some cases.

The end of the protrusion (14) before the assembly thereof is prepared so that it does not touch the surface of the opposite heat sink (1) or shield can (7), and the TIM (6) installed between the heat sink (1) and the shield can (7) is prepared so that it has elasticity in the thickness direction. If this TIM (6) is placed in the inner area of the protrusion (14), the heat sink (1) is pressed downward while the protrusion (14) is melted during the interfacial bonding, and the height can be adjusted according to the degree of melting.

In this case, the mounting tolerance that is a problem during the interface bonding between the shield can (7) and the heat sink (1) can be resolved, and electromagnetic shielding and heat dissipation, weight reduction, and miniaturization can all be achieved.

FIG. 4F illustrates a configuration similar to that FIG. 4E, but with the heat dissipation coating layer (11) is coated on the heat sink (1).

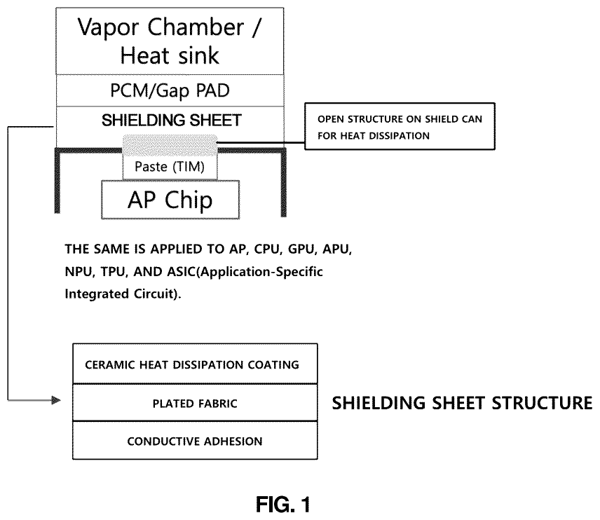

With reference to a structure in FIG. 4A, compared to the structure of the prior art in FIG. 1, a basic four-layer configuration of the heat sink (1), the shield can (7), the TIM (6) or the paste, and the chip (5) is illustrated, but the heat sink (1) and the shield can (7) are surface-bonded to form three layers in reality, and even a structure of FIG. 4B in which the heat dissipation coating is performed has only four layers. Hence, it can be found that the number of layers is significantly reduced compared to the structure of the prior art in FIG. 1.

Consequently, the air gap is still further reduced, and thus good heat dissipation performance is achieved.

Additionally, the structure of the prior art in FIG. 1 uses fiber fabric, so even if fiber fabric is plated, the vertical thermal conductivity is 2 W/mk or lower, and thus it is basically impossible to transfer much heat from the AP chip to the vapor chamber. In contrast, in the example, the fiber fabric is excluded by performing bonding of the vapor chamber and the shield can, and materials having high vertical thermal conductivity are used in a structure in which pure metals are in continuous contact with each other through interfacial adhesion of the shield can made of nickel brass (61.67 wt % of copper, 0.5 wt % of manganese, 16.5 to 19.5 wt % of nickel, and zinc as balance) and the metal vapor chamber. Hence, the heat dissipation effect is improved by at least 8 to 10° C. compared to the structure illustrated in FIG. 1.

In addition, since the metal component of the vapor chamber is grounded by electrically connecting through the interfacial bonding with the shield can (7), the electromagnetic wave shielding can be achieved smoothly.

Moreover, the heat sink (1) made of a pure material without impurities becomes lighter compared to the heat sinks in the prior art, and the volume of the heat sink (1) can be minimized through the press-forming process.

According to the present invention, it is to provide a high-heat-dissipation hybrid-composite heat sink having smooth electromagnetic wave shielding, which minimizes the number of layers and suppresses air gaps through surface-to-surface bonding of contact surfaces between the layers, thereby improving heat dissipation performance, and also enables electromagnetic wave shielding, which is the basic purpose of a shield can, to be smoothly achieved.

Further, the present invention is to provide an ultra-compact and ultra-light heat dissipation structure that improves heat dissipation performance and has light weight and small volume by solving problems of a die casting material in the prior art which has heat dissipation performance degraded due to inclusion of a foreign substance and has large volume and heavy weight.

More specifically, a heat sink and a shield can, such as a vapor chamber, are surface-to-surface bonded (the metal component of the vapor chamber is interfacially bonded to the shield can) through side surfaces around an opening to be electrically connected, so that they can be grounded to ensure smooth electromagnetic wave shielding. In addition, since the heat sink and the shield can are surface-bonded to each other, the number of the layers is minimized with a three-layer structure of an AP chip, a TIM, and a heat sink, thereby achieving an air gap minimization and improving a heat dissipation effect.

In addition, unlike die casting which is a metal casting process of forcing molten metal to be injected into a mold under high pressure, the present invention is to provide a heat sink having high heat dissipation performance for the same weight and volume, the heat sink being made of a plate, an extruded material, a vapor chamber, a heat pipe, or the like which has a maximized content of metal with a high thermal conductivity to minimize weight and volume compared to the die casting material and minimizing the number of layers by performing surface-to-surface bonding to an attachment under the heat sink such as interfacial bonding while air gaps are minimized compared to the prior art.

It will be apparent to those skilled in the art that various modifications and variations can be made in the present invention without departing from the spirit or scope of the present invention as defined in the appended claims.

This invention can be implemented in many different forms without departing from technical aspects or main features. Therefore, the implementation examples of this invention are nothing more than simple examples in all respects and will not be interpreted restrictively.

What is claimed is:

1. A high-heat-dissipation hybrid-composite heat sink having smooth electromagnetic wave shielding comprising:
a heat sink (1) that is made of any one of materials such as aluminum, copper, magnesium, stainless steel, gold, silver, titanium, iron, nickel brass, carbon fiber, and clad metal and is formed in any one form of a plate, an extruded material, a vapor chamber, or a heat pipe; and
an attachment (13) that is positioned under the heat sink (1) and has an opening (7a) formed in a center of a contact surface with the heat sink (1) and an upper surface around the opening (7a) surface-bonded to the heat sink (1) without an air gap.

2. The high-heat-dissipation hybrid-composite heat sink having smooth electromagnetic wave shielding according to claim 1,
wherein the attachment (13) is surface-bonded to the heat sink without an air gap by any one method of arc stud welding, ultrasonic welding, spark plasma sintering welding, laser welding, brazing, soldering, or insulation bonding.

3. The high-heat-dissipation hybrid-composite heat sink having smooth electromagnetic wave shielding according to claim 2,
wherein the attachment (13) includes:
a chip (5);
a TIM (6) formed on an upper portion of the chip (5); and
a shield can (7) having a plate-shaped upper surface positioned on an upper portion of the TIM (6), the opening (7a) formed in a center thereof, and a side portion that forms a wall surface bent downward.

4. The high-heat-dissipation hybrid-composite heat sink having smooth electromagnetic wave shielding according to claim 3,
wherein a lower end of the wall surface of the shield can (7) is grounded and the shield can (7) and the heat sink (1) are interfacially bonded with a conductive material to shield electromagnetic waves.

5. The high-heat-dissipation hybrid-composite heat sink having smooth electromagnetic wave shielding according to claim 3,
wherein the TIM (6) is also placed between the heat sink (1) and the shield can (7) and a protrusion (14) is formed in which an outer perimeter of the heat sink (1) protrudes downward or an outer perimeter of the shield can (7) protrudes upward, so that the heat sink (1) and the shield can (7) are surface-bonded to each other through a cross section of the protrusion (14).

6. The high-heat-dissipation hybrid-composite heat sink having smooth electromagnetic wave shielding according to claim 1,
wherein, on the heat sink (1), a heat dissipation coating layer (11) is formed by roll coating.
